(19) United States
(12) Patent Application Publication
(10) Pub. No.: US 2026/0096473 A1
(43) Pub. Date: Apr. 2, 2026

(54) INTEGRATED CIRCUIT DIE STACK WITH A BACK-SIDE POWER DELIVERY NETWORK

(71) Applicant: Advanced Micro Devices, Inc., Santa Clara, CA (US)

(72) Inventors: Deepak Vasant KULKARNI, Austin, TX (US); Liwei WANG, Austin, TX (US); Raja SWAMINATHAN, Austin, TX (US); Alan D. SMITH, Austin, TX (US)

(21) Appl. No.: 18/900,440

(22) Filed: Sep. 27, 2024

(51) Int. Cl. H01L 25/065; H01L 23/498; H01L 25/00; H01L 25/18; H10B 80/00

(52) U.S. Cl. CPC H10W 90/00; H10B 80/00; H10W 70/65

(57) ABSTRACT

An integrated circuit (IC) device includes a first IC die, a second IC die, an interposer die, and a third carrier substrate. The first IC die includes a first carrier substrate, first transistors, and a first power delivery network. The second IC die includes a second carrier substrate, second transistors, and a second power delivery network. A first surface of the first IC die and a first surface of the second IC die are disposed on the IC interposer die. The first power delivery network is between the IC interposer die and the first transistors and the second power delivery network is between the IC interposer die and the second transistors. The third carrier substrate is attached to a second surface of the first IC die and a second surface of the second IC die.

### BACKGROUND

### Field of the Invention

Implementations described herein generally relate to integrated circuit (IC) die stacks having a back-side power delivery network (PDN) and multiple carrier substrates.

### Description of the Related Art

Multiple integrated circuit (IC) chips are vertically mounted, forming a three-dimensional (3D) stackup. The IC chips are bonded to each other via a face to back bonding method. In a face to back bonding method, the metal layers of a first IC die and the metal layers of a second IC die are facing down, and are separated from each other. Further, a common set of metal layers within the IC dies are used for both signal and power delivery to the transistors of the IC dies. Accordingly, larger cells are used to account for both signal and power delivery to the transistors of the IC dies through the same metal layer stackup. Alternatively, thinner metal layers used for signal and power delivery are used, decreasing the performance of the corresponding power delivery network.

### SUMMARY

In one example, an integrated circuit (IC) device includes a first IC die, a second IC die, an interposer die, and a third carrier substrate. The first IC die includes a first carrier substrate, first transistors, and a first power delivery network. The second IC die includes a second carrier substrate, second transistors, and a second power delivery network. A first surface of the first IC die and a first surface of the second IC die are disposed on the IC interposer die. The first power delivery network is between the IC interposer die and the first transistors and the second power delivery network is between the IC interposer die and the second transistors. The third carrier substrate is attached to a second surface of the first IC die and a second surface of the second IC die.

In one example, a packaged device includes a first substrate, a memory die disposed on the first substrate, and an IC device. The IC device is disposed on the first substrate and coupled to the memory die. The IC device includes a first IC die, a second IC die, an interposer die, and a third carrier substrate. The first IC die includes a first carrier substrate, first transistors, and a first power delivery network. The second IC die includes a second carrier substrate, second transistors, and a second power delivery network. A first surface of the first IC die and a first surface of the second IC die are mounted to the IC interposer die. The first power delivery network is between the IC interposer die and the first transistors and the second power delivery network is between the IC interposer die and the second transistors. The third carrier substrate is attached to a second surface of the first IC die and a second surface of the second IC die.

A method of forming a packaged device includes providing a first substrate. The method further includes mounting an IC device to the first substrate. The IC device includes a first IC die, a second IC die, an interposer die, and a third carrier substrate. The first IC die includes a first carrier substrate, first transistors, and a first power delivery network. The second IC die includes a second carrier substrate, second transistors, and a second power delivery network. A first surface of the first IC die and a first surface of the second IC die are mounted to the IC interposer die. The first power delivery network is between the IC interposer die and the first transistors and the second power delivery network is between the IC interposer die and the second transistors. The third carrier substrate is attached to a second surface of the first IC die and a second surface of the second IC die.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a block diagram of an integrated circuit (IC) device having one or more IC dies and an IC interposer die.

FIG. 2 illustrates a flowchart of a method for forming an IC device.

FIGS. 3A, 3B, 3C, 3D, 3E, 3F, 3G, 3H, and 3I illustrate various instances of an IC device during the manufacturing process.

FIG. 4 illustrates an IC die having a testing connectors.

FIG. 5 illustrates a block diagram of a package device.

FIG. 6 illustrates a block diagram of a computer system.

To facilitate understanding, identical reference numerals have been used, where possible, to designate identical elements that are common to the figures. It is contemplated that elements of one embodiment may be beneficially incorporated in other embodiments.

### DETAILED DESCRIPTION

In integrated circuit (IC) devices, IC dies may be interconnected to allow the IC dies to function together to perform a task. The IC dies may be horizontally coupled or vertically mounted. Vertically mounting the IC dies forms a three-dimensional (3D) stackup. An IC die has a power delivery network (PDN) formed within metal layers of a first side (e.g., a back-side) of an IC die. Signal layers are formed within metal layers of a second side (e.g., a front side) of an IC die. Transistors are formed in metal layers in a region between the first and second sides of the IC die and are connected to the PDN and signal layers. Further, connections are formed on the back-side of the IC die, and are used to mount the IC die to an IC interposer die. A first carrier substrate is attached to a front-side of the IC die, and used to provide rigidity to the wafer of the IC die during patterning of the PDN within the back-side metal layers.

Two or more IC dies are mounted to a common IC interposer die. The IC interposer die communicatively couples the IC dies with each other. A second carrier substrate is mounted to the first carrier substrate of the two or more IC dies, increasing the rigidity of the corresponding IC device.

In one example, during the method for forming the IC dies, the first carrier substrate allows for the wafer of the IC dies to be thinned before the metal layers and dielectric layers used to form the PDN are disposed and patterned. Accordingly, the metal layers used to form the PDN can be thicker than those to form the signal layers, improving the performance of the PDN. Further, the IC dies described herein allow for 3D stacking of IC dies with back-side power delivery.

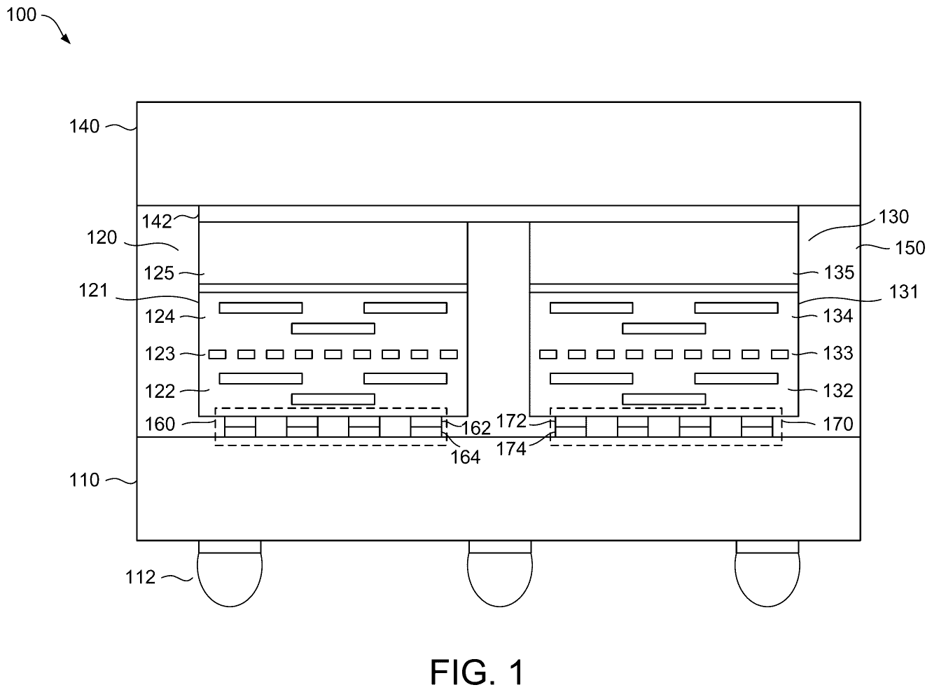

FIG. 1 illustrates an IC device 100, according to one or more examples. The IC device 100 may be referred to an IC chip package. The IC device 100 includes IC interposer die 110, IC dies 120 and 130, and carrier substrate 140. In other examples, the IC device 100 may include more than two IC dies. As is described in greater detail in the following, the IC device 100 may be included as part of an electronic device. For example, the IC device 100 may be mounted (e.g., disposed) to a package substrate of the electronic device, and communicate with other circuit devices within the electronic device to perform one or more functions.

The IC dies 120 and 130 are mounted and disposed on the IC interposer die 110. Mounting the IC dies 120 and 130 to the IC interposer die 110 mechanically and electronically couples (e.g., connects) the IC dies 120 and 130 with the IC interposer die 110. The IC die 120 is mounted to the IC interposer die 110 via connections 160. The connections 160 may be referred to as hybrid bonds. In one example, a hybrid bond includes two materials at the interface between the IC die 120 and the IC interposer die 110. The two materials include silicon oxide dielectric and copper pads. In other examples, other dielectric and/or conductive materials can be used. In one example, during the hybrid bonding process, the surfaces of the connections 160 are treated such that an oxide-to-oxide bond may be created. The oxide-to-oxide bond is created at room temperature. Copper diffusion within the connections 160 is generated and a copper-to-copper bond is formed via a high temperature exposure (e.g., a temperature greater than room temperature). In one example, another conductive material may be used instead of copper in the copper diffusion and the copper-to-copper bonds. Further, the high temperature exposure may occur after the oxide-to-oxide bond is created. In one or more examples, the connections 160 may include bump connections, where bonding pads on the IC die 120 and bonding pads on the IC interposer die 110 are connected via conductive bumps. In other examples, other the connections 160 may be formed using other technologies that provide electrical and physical connections between the IC die 120 and the IC interposer die 110.

The connections 160 include connectors 162 disposed on a surface of the IC die 120 and connectors 164 disposed on a surface of the IC interposer die 110. The surface of the IC die 120 on which the connectors 162 are disposed is parallel to the surface of the IC interposer die 110 on which the connectors 164 are disposed.

The IC die 130 is mounted to the IC interposer die 110 via connections 170. The connections 170 may be referred to as hybrid bonds. In one or more examples, the connections 170 may include bump connections, where bonding pads on the IC die 130 and bonding pads on the IC interposer die 110 are connected via conductive bumps. In other examples, other the connections 170 may be formed using other technologies that provide electrical and physical connections between the IC die 130 and the IC interposer die 110.

The connections 170 include connectors 172 disposed on a surface of the IC die 130 and connectors 174 disposed on a surface of the IC interposer die 110. The surface of the IC die 130 on which the connectors 172 are disposed is parallel to the surface of the IC interposer die 110 on which the connectors 174 are disposed.

In one or more examples, the IC die 120 and the IC interposer die 110 form a first interposer die/compute stack assembly. The IC die 130 and the IC interposer die 110 form a second interposer die/compute stack assembly. In other examples, additional IC dies may be mounted to the IC interposer die 110 forming additional interposer die/compute stack assemblies. In one example, multiple IC dies are vertically stacked with each other and then mounted to the IC interposer die 110 forming an interposer die/compute stack assembly.

The IC interposer die 110 includes a plurality of routing connections configured to couple to the connections 160 and 170. The routing connections and the connections 160 and 170 provide data connections between the IC dies 120 and 130. In one or more examples, the routing connections and the connections 160 and 170, additionally or alternatively, provide connections between the IC dies 120 and/or 130, and an external IC device (e.g., a memory device and/or a processing device, among others). The pitch among the connections 160 and 170 is less than 10 μm, 5 μm, or 1 μm. The connectors 164 and 174 provide a significantly denser pitch of connections than wire bonds or micro solder balls. As a result, the communication bandwidth between the IC dies 120 and 130 is significantly greater than devices that use connections different from the connections (e.g., hybrid bonds) 160 and 170. In one or more examples, the IC interposer die 110 includes through silicon vias (TSVs) that couple with the IC dies 120 and 130. The TSVs couple external circuitry elements (e.g., memory devices and/or processing devices, among others, that are external to the package device 100) to the IC die 120 and/or the IC die 130. The TSVs within the IC interposer die 110 transfer several types of signals, including power, ground connection, data signal, testing signals, control signal, timing signal, encryption signal, or any other signals transmitted from an IC device to another IC device.

In one or more examples, the IC interposer die 110 includes functional circuity. The functional circuitry includes memory controller circuitry coupled to one or more of the IC dies 120 and 130. The memory controller circuitry may be coupled to one or more of the IC dies 120 and 130 without routing signals through another substrate and/or interposer. Additionally, or alternatively, the functional circuitry of the IC interposer die 110 includes cache memory circuitry. The cache memory circuitry is coupled to one or more of the IC dies 120 and 130. In one example, the cache memory circuitry is coupled to one or more of the IC dies 120 and 130 without routing signals through another substrate and/or interposer. The cache memory circuitry provides a common cache to one or more of the IC dies 120 and 130.

In one or more examples, the functional circuitry of the IC interposer die 110, additionally, or alternatively, includes peripheral interconnect circuitry (e.g., peripheral component interconnect express (PCIe) circuitry, physical layer (PHY) circuitry, input/output (I/O) circuitry, among others). The peripheral interconnect circuitry provides for communication between the IC die 120 and/or the IC die 130, between the IC die 120 and/or the IC die 130 and an another IC die, and/or between the IC die 120 and/or the IC die 130 and an external IC die or circuitry (e.g., an IC die and/or circuitry external to the IC interposer die 110).

In one or more examples, the functional circuitry of the IC interposer die 110 additionally, or alternatively, includes serializer/deserializer (SERDES) circuitry that is used in high-speed chip-to-chip communication. Additionally, or alternatively, the functional circuitry of the IC interposer die 110 includes circuitry that performs the functions of a network-on-chip.

As is described in greater detail in the following, the IC interposer die 110 is mounted and/or disposed on a substrate (e.g., a package substrate or interposer) via the connectors 112. The connectors 112 may be a plurality of solder connectors. The connectors 112 are coupled to connectors on the substrate, forming an electrical and physical connection between the IC interposer die 110 and the substrate.

The IC die 120 may be a programmable logic device, such as field programmable gate arrays (FPGA), a memory device, an optical device, a processing device, (e.g., an accelerator device, central processing unit (CPU) or a graphics processing unit (GPU), among others) or other IC logic structures. The IC die 120 may be referred to as a chip die. For example, the IC die 120 includes a die body 121. The die body 121 includes PDN 122, transistors 123, and signal layers 124 formed within metal layers and dielectric layers. The metal layers and dielectric layers are interleaved with each other. In one or more examples, the metal layers are patterned to form the PDN 122, the transistors 123, and the signal layers 124. The die body 121 is attached to the carrier substrate 125 of the IC die 120. In one example, the die body 121 is attached to the carrier substrate 125 via an oxide fusion bond layer and/or one or more metal connectors.

The PDN 122 is formed within metal and/or dielectric layers of the IC die body 121. For example, the PDN 122 is formed by patterning one or more of the metal layers and dielectric layers of the IC die body 121. In one example, forming the PDN 122 includes disposing dielectric layers and metal layers. The metal layers and dielectric layers are patterned to form the PDN 122. Further, vias are formed and used to connect the patterned the metal layers to from the PDN 122.

The transistors 123 are formed within layers (e.g., metal and/or dielectric layers) of the IC die 120. Metal layers and dielectric layers are patterned to form the transistors 123. Further, vias are used to connect the patterned metal layers to form the transistors 123. Further, vias may be used to couple the transistors 123 with the PDN layers 122.

The signal layers 124 are formed within metal and/or dielectric layers of the IC die body 121. For example, the signal layers 124 are formed by patterning the metal layers and dielectric layers of the IC die body 121. Vias are formed within the metal layers and/or dielectric layers to connect the patterned metal layers to from the signal layers 124. In one or more examples, vias are used to connect the patterned signal layers 124 with the transistors 123.

In one example, the thickness of the metal layers forming the PDN layers 122 is greater than the thickness of the metal layers forming the signal layers 124. Accordingly, the resistance of the metal layers forming the PDN layers 122 is less than the resistance of the metal layers forming the signal layers 124.

The carrier substrate 125 is coupled to the die body 121. In one example, the carrier substrate 125 is coupled to the die body 121 via an oxide layer or another bonding layer. In one or more examples, the carrier substrate 125 is coupled to the die body 121 via a metal bonding layer or layers (e.g., hybrid bonds or another metal bonding layer). In one example, the carrier substrate 125 is formed of a silicon material. In one or more examples, the carrier substrate 125 is formed of another material. The carrier substrate 125 allows for the wafer of the IC die 120 to be thinned before the metal layers and dielectric layers used to form the PDN 122 are disposed and patterned. Accordingly, the thickness of metal layers used to form the PDN 122 can be greater than those used to form the signal layers 124, improving the performance of the PDN 122.

In one example, the thickness of the carrier substrate 140 is greater than a thickness of the carrier substrate 125. In another example, the thickness of the carrier substrate 140 is less than or equal to the thickness of the carrier substrate 125. The thickness of the carrier substrate 140 is selected to provide rigidity to the IC device 100 when the IC interposer die 110 is thinned. The carrier substrate 140 provides additional rigidity and support to the IC device 100, mitigating damage and warpage that may occur to the IC device 100 during a corresponding semiconductor manufacturing process, increasing the semiconductor production yield and decreasing the cost of manufacturing the semiconductors.

The IC die 130 may be a programmable logic device, such as FPGA, a memory device, an optical device, a processing device, (e.g., an accelerator device, CPU or a GPU, among others) or other IC logic structures. The IC die 130 may be referred to as a chip die or IC die. For example, the IC die 130 includes a die body 131. The die body 131 includes PDN (PDN layers) 132, transistors 133, and signal layers 134 formed within metal layers and dielectric layers. The metal layers and dielectric layers are interleaved with each other. In one or more examples, the metal layers are patterned to form the PDN 132, the transistors 133, and the signal layers 134. The die body 131 is attached to the carrier substrate 135 of the IC die 130. In one example, the die body 131 is attached to the carrier substrate 135 via an oxide fusion bond layer and/or one or more metal connectors. The carrier substrate 135 allows for the wafer of the IC die 130 to be thinned before the metal layers and dielectric layers used to form the PDN 132 are disposed and patterned. Accordingly, the thickness of metal layers used to form the PDN 132 can be greater than those used to form the signal layers 134, improving the performance of the PDN 132.

The PDN 132 is formed within metal and/or dielectric layers of the IC die body 131. For example, the PDN 132 is formed by patterning one or more of the metal layers and dielectric layers of the IC die body 131. In one example, forming the PDN 132 includes disposing dielectric layers and metal layers. The metal layers and dielectric layers are patterned to form the PDN 132. Further, vias are formed and used to connect the patterned the metal layers to from the PDN 132.

The transistors 133 are formed within layers (e.g., metal and/or dielectric layers) of the IC die 130. Metal layers and dielectric layers are patterned to form the transistors 133. Further, vias are used to connect the patterned metal layers to form the transistors 133. Vias may be used to couple the transistors 133 with the PDN 132.

The signal layers 134 are formed within metal and/or dielectric layers of the IC die body 131. For example, the signal layers 134 are formed by patterning the metal layers and dielectric layers of the IC die body 131. Vias are formed within the metal layers and/or dielectric layers to connect the patterned metal layers to from the signal layers 134. In one or more examples, vias are used to connect the patterned signal layers 134 with the transistors 133.

In one example, the thickness of the metal layers forming the PDN 132 is greater than the thickness of the metal layers forming the signal layers 134. Accordingly, the resistance of the metal layers forming the PDN 132 is less than the resistance of the metal layers forming the signal layers 134.

The carrier substrate 135 is coupled to the die body 131. In one example, the carrier substrate 135 is coupled to the die body 131 via an oxide layer or another bonding layer. In one or more examples, the carrier substrate 135 is coupled to the die body 131 via a metal bonding layer or layers (e.g., hybrid bonds or another metal bonding layer). In one example, the carrier substrate 135 is formed of a silicon material. In one or more examples, the carrier substrate 135 is formed of another material.

In one example, the thickness of the carrier substrate 140 is greater than a thickness of the carrier substrate 135. In another example, the thickness of the carrier substrate 140 is less than or equal to the thickness of the carrier substrate 135. The thickness of the carrier substrate 140 is selected to provide rigidity to the IC device 100 when the IC interposer die 110 is thinned.

Dielectric material 150 is disposed between and around the IC dies 120 and 130. The dielectric material 150 is disposed above the IC interposer die 110. The dielectric material 150 increases the structural rigidity and reduces the probability of warpage of the IC device 100. In one or more examples, dielectric material 150 may be may be a molding compound, a gap fill oxide, or other suitable dielectric material. In one example, the dielectric material 150 is a silicon-based dielectric film, such as SiO or SiN, among others.

In one example, two or more IC dies are stacked on each other. In such an example, at least one of the IC dies in the stack is formed described herein. In one or more examples, the top most IC die is formed as described herein.

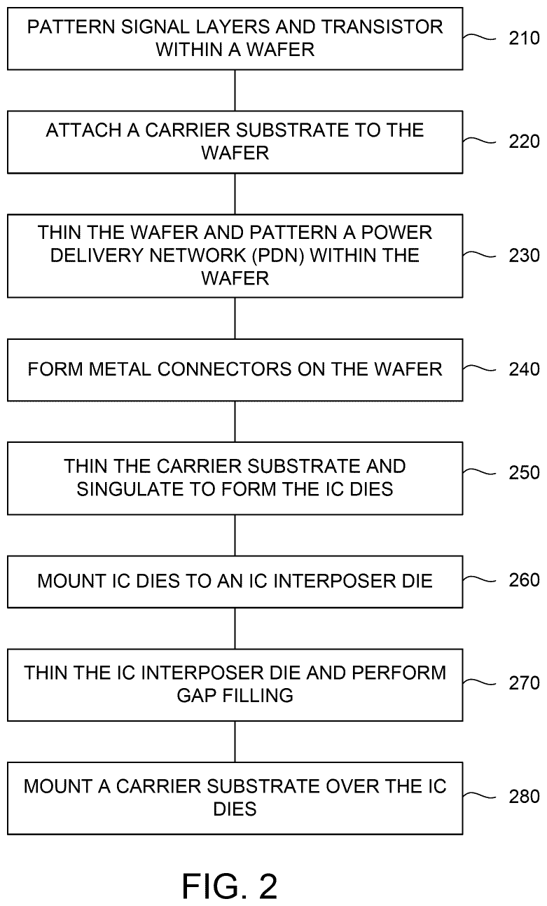

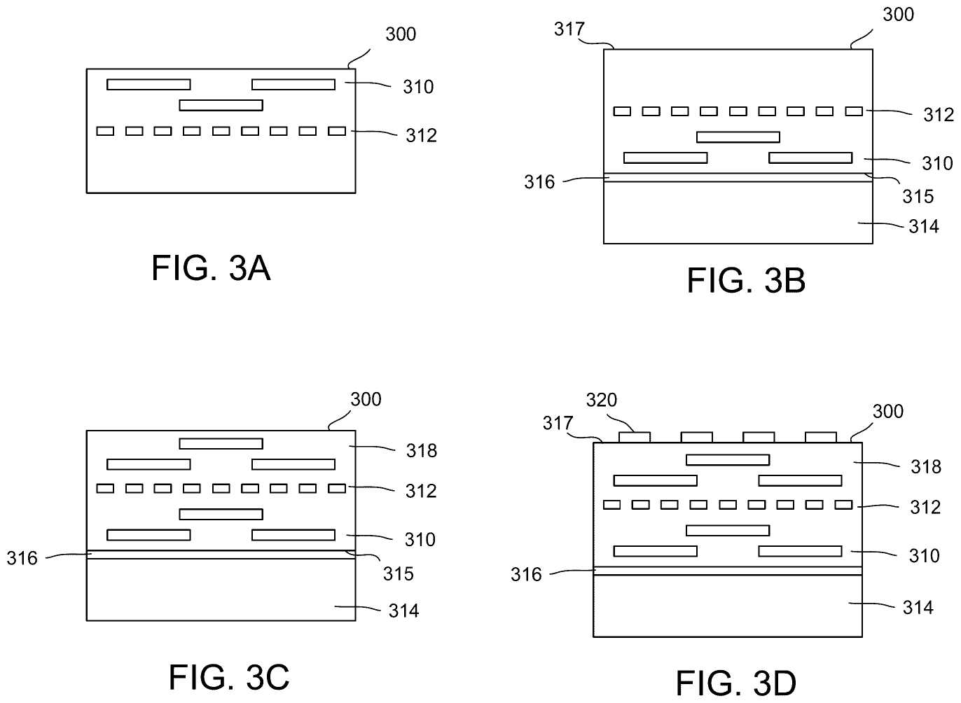

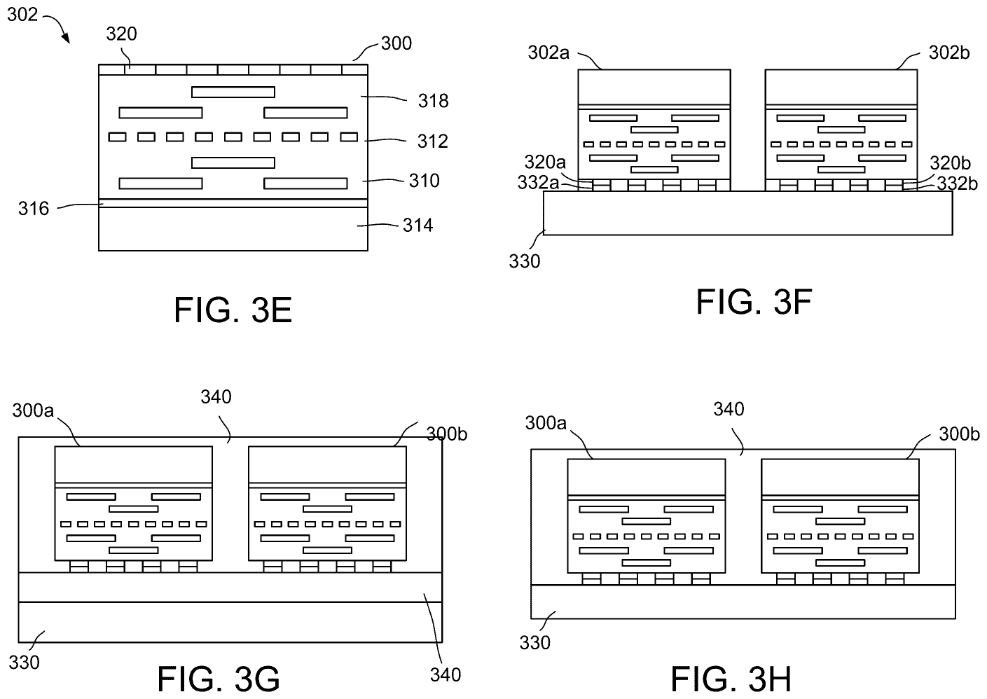

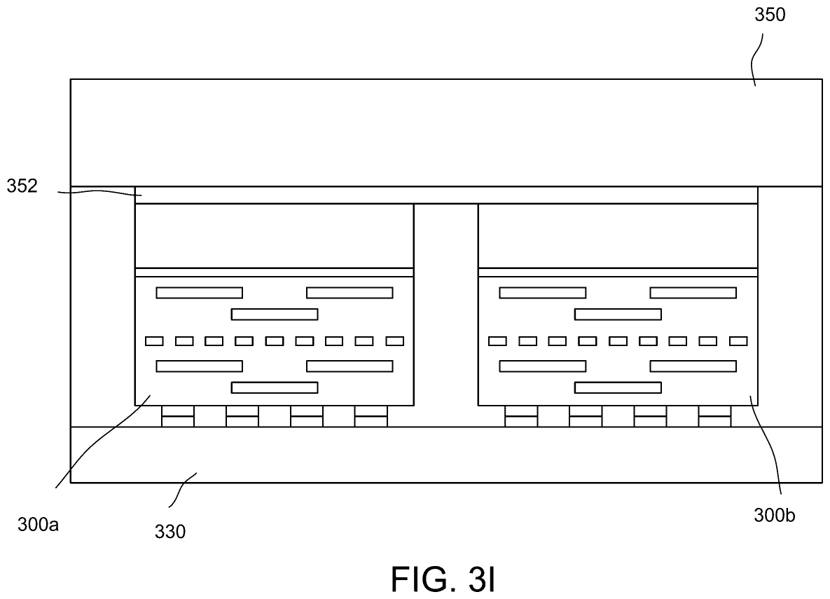

FIG. 2 illustrates a flowchart of a method 200 for forming an IC device (e.g., the IC device 100 of FIG. 1). At 210 of the method 200, signal layers and transistors are patterned within a wafer. For example, with reference to FIG. 3A, the signal layers 310 and the transistors 312 are patterned within the wafer 300. Patterning the signal layers and transistors includes depositing one or more metal layers and one or more dielectric layers on the wafer 300. The metal layers and dielectric layers are interleaved with each other. The metal layers and dielectric layers are patterned to form the signal layers and the transistors. Further, vias are formed within the metal layers and the dielectric layers to connect the patterned layers. In one example, vias are used to connect the transistors 312 to the signal layers 310.

At 220 of the method 200, a carrier substrate is attached to the wafer. For example, with reference to FIG. 3B, the carrier substrate 314 is attached to the wafer 300. The carrier substrate 314 is attached to the wafer 300 on the surface 315 proximate the signal layers 310. In one example, the carrier substrate 314 is attached to the surface 315 of the wafer 300 with fusion bonding via the bonding layer 316. For example, the oxide layer 316 is disposed on the surface 315 of the wafer 300. The carrier substrate 314 is then attached to the wafer 300 via fusion bonding. In other examples, other bonding techniques may be used. The other bonding techniques include metal-to-metal bonding techniques, among others.

At 230 of the method 200, the wafer is thinned and a PDN is patterned within the wafer. For example, as is illustrated in FIGS. 3B and 3C, the surface 317 of the wafer 300 (e.g., the surface that is not connected to the carrier substrate 314) is thinned. In one example, thinning the wafer 300 includes grinding the surface 317 of the wafer 300 to remove material of the wafer 300. Thinning the wafer 300 reduces the amount of material that is above the transistors 312, reducing the stackup height of the wafer 300 and the corresponding IC device.

In one example, patterning the PDN 318 includes forming (e.g., depositing or forming in another way) dielectric layers (e.g., insulating layers) and metal layers on the thinned wafer 300. The metal layers and dielectric layers are interleaved with each other. The metal layers and the dielectric layers are patterned to form the PDN 318. In one example, vias within the metal layers and/or the dielectric layers are formed and used to interconnect the patterned the metal layers. In one or more examples, vias are further used to connect the patterned metal layers (e.g., the PDN 318) with the transistors 312. In one example, the thickness of the metal layers forming the PDN 318 is greater than the thickness of the metal layers forming the signal layers 310. Accordingly, the resistance of the metal layers forming the PDN 318 is less than the resistance of the metal layers forming the signal layers 310.

In one example, the PDN 318 is formed using a back-side of the wafer 300. In a back-side PDN, the front-end metal layers are separated into two categories, signal layers and PDN layers. The PDN layers are on the back-side of the transistor layer (e.g., transistors 312). The PDN layers on the back-side can be tuned (e.g., adjust a thickness of) to reduce IR drop and/or to improve efficiency of the PDN 318. The compactness of the signal layers 310 can be increased, as the PDN 318 does not interfere with the signal layers 310 resulting in a saving of the silicon area of the corresponding IC device. In one or more examples, the use of a back-side PDN (e.g., the PDN 318) provide an improved power delivery via the PDN 318, a reduction in silicon area, and improved performance of the transistors 312.

At 240 of the method 200, metal connectors are formed on the wafer. For example, as is illustrated in FIG. 3D, the metal connectors (pads) 320 are formed on the wafer 300. The metal connectors 320 are formed on the surface 317 of the wafer 300 opposite the carrier substrate 314. The metal connectors 320 are formed over the PDN 318. In one example, the metal connectors 320 are coupled through vias to the PDN 318, the transistors 312, and/or the signal layers 310. The metal connectors 320 are used to form a metal-to-metal bond. In one or more examples, the metal connectors 320 form hybrid bond connectors formed during a hybrid boding processes. In one or more examples, the metal connectors 320 are formed by depositing a metal layer (or layers) and patterning the metal layer (or layers) to form the metal connectors 320. In one example, a dielectric material is formed around the metal connectors 320.

In one example, a common fabrication process is used to form the metal connectors 320 on the wafer 300 and to form the PDN 318. The fabrication process includes completing a lithographic process to pattern (form) the PDN 318 on the thinned wafer 300, which is attached to the carrier substrate 214. The metal connectors 320 are formed as part of the lithographic process that is used to pattern the PDN 318. Using the same fabrication process (e.g., lithographic process) to form the PDN 318 and the connectors 320 reduces the number of fabrication steps that are used to form the corresponding IC device. For example, in an example where a combined fabrication is not used, before the connectors 320 are formed, the wafer 300 is cleaned and planarized in preparation for forming the connectors 320. As the wafer 300 is already thinned and mounted to the carrier substrate 314, the lithographic process used to pattern the PDN 318 can be used to form the connectors 320, mitigating multiple re-entries into corresponding fabrication and packaging sites, and reducing manufacturing cycle time.

At 250 of the method 200, the carrier substrate is thinned and singulation is performed to form the IC dies. For example, as is illustrated in FIG. 3E, the carrier substrate 314 is thinned, reducing the thickness of the carrier substrate 314. Further, die singulation (dicing) is performed to form individual IC dies 302. Singulation may include breaking, dicing, or cutting the wafer 300 to form the individual IC dies.

At 260, IC dies are mounted to an IC interposer die. In one or more examples, two or more IC dies are mounted to an IC interposer die. With reference to FIG. 3F, the IC die 302a and 302B are mounted to the IC interposer die 330. The IC interposer die 330 includes metal connectors 332a and 332b. The metal connectors 320a of the IC die 302a are mounted with the metal connectors 332a to mount the IC die 302a to the IC interposer die 330. The metal connectors 320b of the IC die 302b are mounted with the metal connectors 332b to mount the IC die 302b to the IC interposer die 330. In one example, the metal connectors 322 and 332 form hybrid bonds. The hybrid bonds include metal-to-metal bonds formed by a hybrid bonding process. For example, the metal-to-metal bonds may be formed using pressure and heat to form eutectic metal bonds. A hybrid bond may be formed by bonding the dielectric materials surrounding bond pads to secure the IC dies 302a and 302b, followed by an interfusion of the metal materials of the metal connectors to create the electric interconnect. The dielectric material surrounding the metal connectors is selected from a material suitable for hybrid bonding to another dielectric material. Materials that are suitable for hybrid bonding include polybenzoxazole (PBO), polyimide (PI), benzocyclobutene (BCB), a combination thereof, or the like.

In one or more example, mounting the IC dies 302a and 302b to the IC interposer die 330 as described above (e.g., with the PDN 318 and surface 317 facing the IC interposer die 330) improves power delivery with a lower IR drop (e.g., voltage drop that occurs due to the flow of current and a resistance that affects the flow of current) as the PDN 318 is directly connected to the IC interposer die 330.

In one example, as illustrated in FIG. 3G, an interposer 340 (e.g., a silicon-on-insulator wafer) is disposed between the IC interposer die 330 and the IC dies 302a and 302b. In such an example, the IC dies 302a and 302b are mounted to the interposer 340 as is described above with regard to the IC interposer die 330. The interposer 340 is mounted to the IC interposer die 330. Further, connections between the IC dies 302 are formed within the interposer 340 and/or the IC interposer die 330. The interposer 340 is an organic interposer, silicon interposer, or an organic interposer with embedded silicon bridges. The interposer 340 provides additional routing layers (e.g., metal layers) that may be used for connections between the IC dies 302a and 302b, and/or fanout connections between one or more of the IC dies 302a and 302b and the interposer die 330. In one or more examples, the IC interposer die 330 does not include enough metal layers and/or the correct configuration of metal layers to provide (e.g., form) the connections (e.g., routings) between the IC dies 302a and 302b. In such examples, the interposer 340 is included such that one or more of the connections between the IC dies 302a and 302b can be formed in the metal layers of the interposer 340. In one or more examples, each of the connections (e.g., routings) between the IC dies 302a and 302b are formed in the metal layers of the interposer 340. In other examples, the IC interposer die 330 may experience warpage in response to the fabrication processes. In such examples, the IC interposer 340 may be mounted to the IC interposer die 330 to mitigate warpage of the interposer die 330. In one example, the connection pitch of the interposer 340 is aligned with that of the IC die 302a and 302b, improving the mounting process between the IC dies 302a and 302b and the interposer die 330.

At 270 of the method 200, the IC interposer die is thinned and gap filling is performed. With reference to FIG. 3H, the IC interposer die 330 is thinned. For example, grinding is performed on the IC interposer die 330 to thin the IC interposer die 330. Further, gap filling is performed around the IC dies 302a and 302b, forming a dielectric material 340 around the IC dies 302a and 302b.

At 280 of the method 200, a carrier substrate is mounted to the IC dies. For example, with reference to FIG. 3I, the carrier substrate 350 is mounted to the IC dies 302a and 302b. An oxide layer 352 is disposed between the carrier substrate 350 and the IC dies 302a and 302b, and used to fusion bond the carrier substrate 350 to the IC dies 302a and 302b. In other examples, other bonding techniques may be used to mount the carrier substrate 350 to a surface of the IC dies 302a and 302b. In one or more examples, a metal-to-metal bonding process (e.g., hybrid bonding or the like) is used to mount the carrier substrate 350 with a surface of the IC dies 302a and 302b.

In one example, connectors (e.g., the connectors 112 of FIG. 1) are formed on the IC interposer die 330. As is described above, the connectors may be used to couple (e.g., mount or attach) the IC interposer die 330 to a substrate (e.g., a package substrate, an interposer, or another type of substrate).

In one example, an IC device formed as described with regard to the method 200 reduces the die area of the IC die by combining 3D stacking with back-side power delivery. Further, the manufacturing process time for such an IC device is reduced as steps are combined for patterning the PDN 318 and the connectors 320.

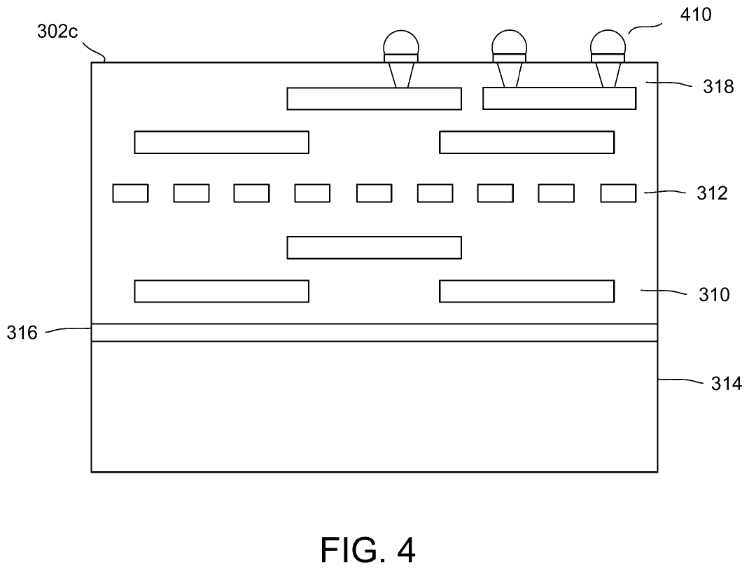

FIG. 4 illustrates an example of an IC die 302c where test connectors 410 are formed on the IC die 302c. The test connectors 410 are used during evaluation of the IC die 302c. The test connectors 410 may be referred to as sacrificial connectors or bumps. After evaluation of the IC die 302c is completed, the test connectors 410 are removed. For example, the test connectors 410 are etched away to remove the test connectors 410. The connectors 320 are formed on the IC die 302c after the test connectors 410 are removed. In one example, with reference to the method 200 of FIG. 2, the test connectors 410 are formed on the IC die 302c and the IC die 302 is evaluated before 240 of the method 200, forming the metal connectors on the wafer. In one or more examples, the test connectors 410 minimize the area of the IC die 302 used for evaluation (or test) as dedicated testing probe connections are not used.

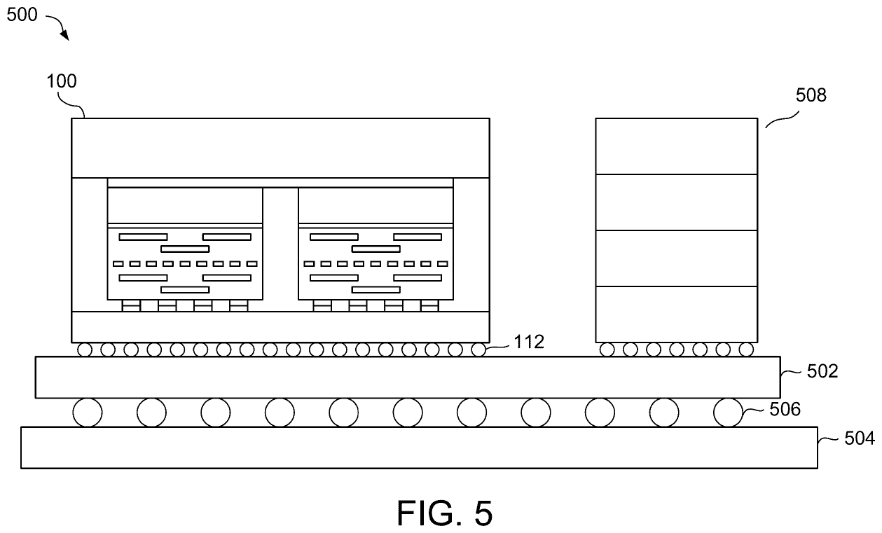

FIG. 5 illustrates a chip package 500. The chip package 500 includes the IC device 100 mounted to the substrates 502 and 504. The substrate 502 may be an interposer. The substrate 504 may be a package substrate. In one example, the IC device 100 is mounted and coupled to the substrate 502 via connections 112. The IC dies 116 are mounted to the substrate 502 and connected to the IC device 100 via the connections within the substrate 502. The IC dies 116 may be memory dies. In other examples, the IC dies 116 may be other types of dies. Further, in one or more examples, the IC dies 116 may include one or more IC dies.

The substrate 502 is coupled with the substrate 504 via the connections 506. The substrate 502 may be a package substrate. The substrate 504 may couple the chip package 500 with other devices. For example, a processing device (e.g., CPU or GPU, among others) may be coupled to the substrate 504 or to another substrate coupled to the substrate 504. The processing device communicates with the IC device 100 and/or the IC dies 508 to perform one or more processes.

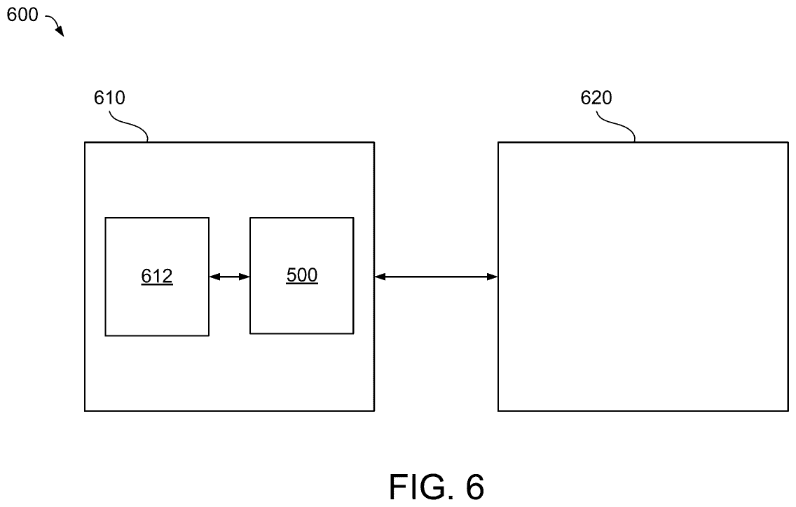

FIG. 6 illustrates computer system 600. The computer system 600 includes computer device 610 and computer device 620. The computer device 610 includes a processing device 612 and the chip package 500. The processing device 612 is coupled with the chip package 500. The processing device 612 communicates with the chip package 500 to perform one or more processes (or tasks). In one example, the computer device 610 includes two or more chip packages 500. In such an example, the processing device 612 is coupled with each of the chip packages 500, and communicates with the chip packages 500 to perform one or more tasks. The chip packages 500 may be directly connected with each other and/or connected with each via the processing device 612.

The computer device 610 may be one computer device of a distributed computer system. In such an example, the computer device 610 and the computer device 620 are connected with each other and communicate with each other to perform one or more processes. The computer device 610 and/or the computer device 620 may be referred to as server devices. In one example, one of the computer device 610 and the computer device 620 is configured as a host device. In one example, the computer device 620 has a similar configuration as the computer device 610, including one or more processing devices 612 and chip packages 500. While the computer system 600 is illustrated has having two interconnected computer devices, in other examples, the computer system 600 may have more than two interconnected computer devices. In other examples, the computer system 600 may have one computer device.

While the foregoing is directed to embodiments of the present invention, other and further embodiments of the invention may be devised without departing from the basic scope thereof, and the scope thereof is determined by the claims that follow.

What is claimed is:

1. An integrated circuit (IC) device comprising:
a first IC die comprising a first carrier substrate, first transistors, and a first power delivery network;
a second IC die comprising a second carrier substrate, second transistors, and a second power delivery network;
an IC interposer die, wherein a first surface of the first IC die and a first surface of the second IC die are disposed on the IC interposer die, wherein the first power delivery network is between the IC interposer die and the first transistors and the second power delivery network is between the IC interposer die and the second transistors; and
a third carrier substrate attached to a second surface of the first IC die and a second surface of the second IC die.

2. The IC device of claim 1, wherein the first IC die further comprises first signal layers, wherein a thickness of metal layers forming the first power delivery network is greater than a thickness of metal layers forming the first signal layers.

3. The IC device of claim 2, wherein the first transistors are formed between the first signal layers and the first power delivery network.

4. The IC device of claim 3, wherein first connectors are disposed on the first surface of the first IC die, and wherein the first connectors are connected to second connectors disposed on the IC interposer die.

5. The IC device of claim 3, wherein the first power delivery network is disposed between the first transistors and the first surface of the first IC die, and wherein the first signal layers are disposed between the first transistors and the second surface of the first IC die.

6. The IC device of claim 1, wherein the IC interposer die comprises functional circuitry configured to perform one or more operations on signals communicated one or more of the first IC die and second IC die.

7. The IC device of claim 1 further comprising an interposer mounted to the IC interposer die, and wherein the first IC die and the second IC die are mounted to the interposer.

8. A packaged device comprising:
a first substrate;
a memory die disposed on the first substrate; and
an integrated circuit (IC) device disposed on the first substrate and coupled to the memory die, the IC device comprising:
a first IC die comprising a first carrier substrate, first transistors, and a first power delivery network;
a second IC die comprising a second carrier substrate, second transistors, and a second power delivery network;
an IC interposer die, wherein a first surface of the first IC die and a first surface of the second IC die are mounted to the IC interposer die, wherein the first power delivery network is between the IC interposer die and the first transistors and the second power delivery network is between the IC interposer die and the second transistors; and
a third carrier substrate attached to a second surface of the first IC die and a second surface of the second IC die.

9. The packaged device of claim 8, wherein the first IC die further comprises first signal layers, wherein a thickness of metal layers forming the first power delivery network is greater than a thickness of metal layers forming the first signal layers.

10. The packaged device of claim 9, wherein the first transistors are formed between the first signal layers and the first power delivery network.

11. The packaged device of claim 10, wherein the first power delivery network is disposed between the first transistors and the first surface of the first IC die, and wherein the first signal layers are disposed between the first transistors and the second surface of the first IC die.

12. The packaged device of claim 8, wherein the IC interposer die comprises functional circuitry configured to perform one or more operations on signals communicated one or more of the first IC die and second IC die.

13. The packaged device of claim 8, wherein the IC device further comprises an interposer mounted to the IC interposer die, and wherein the first IC die and the second IC die are mounted to the interposer.

14. A method of forming a packaged device, the method comprising:
providing a first substrate; and
mounting an integrated circuit (IC) device to the first substrate, wherein the IC device comprises:
a first IC die comprising a first carrier substrate, first transistors, and a first power delivery network;
a second IC die comprising a second carrier substrate, second transistors, and a second power delivery network;
an IC interposer die, wherein a first surface of the first IC die and a first surface of the second IC die are mounted to the IC interposer die, wherein the first power delivery network is between the IC interposer die and the first transistors and the second power delivery network is between the IC interposer die and the second transistors; and
a third carrier substrate attached to a second surface of the first IC die and a second surface of the second IC die.

15. The method of claim 14 further comprising providing a memory die and mounting the memory die to the first substrate to the memory die with the IC device.

16. The method of claim 14, wherein first connectors are formed on the first IC die, and wherein the first power delivery network and the first connectors are formed using a common fabrication process.

17. The method of claim 14, wherein the first IC die further comprises first signal layers, wherein a thickness of metal layers forming the first power delivery network is greater than a thickness of metal layers forming the first signal layers.

18. The method of claim 17, wherein the first power delivery network is disposed between the first transistors and the first surface of the first IC die, and wherein the first signal layers are disposed between the first transistors and the second surface of the first IC die.

19. The method of claim 14, wherein the IC interposer die comprises functional circuitry configured to perform one or more operations on signals communicated one or more of the first IC die and second IC die.

20. The method of claim 14, wherein the IC device further comprises an interposer mounted to the IC interposer die, and wherein the first IC die and the second IC die are mounted to the interposer.
